(19) United States
(12) Patent Application Publication
(10) Pub. No.: US 2008/0022927 A1
(43) Pub. Date: Jan. 31, 2008

(54) Microfluidic device for controlled movement of material

(76) Inventors: Sean Xiao-An Zhang, Cupertino, CA (US); Patricia A. Beck, Palo Alto, CA (US); Janice H. Nickel, Sunnyvale, CA (US)

Correspondence Address: SUGHRUE MION, PLLC, 2100 PENNSYLVANIA AVENUE, N.W., SUITE 800, WASHINGTON, DC, 20037, US

(21) Appl. No.: 11/495,359

(22) Filed: Jul. 28, 2006

(51) Int. Cl. C30B 35/00; C30B 15/00

(52) U.S. Cl. 117/210; 117/205

(57) ABSTRACT

A microfluidic device for controllably moving a material of interest includes a holding cavity configured to hold the material of interest and at least one actuator configured to induce an activation material to expand or contract. Expansion of the activation material decreases the size of the holding cavity to cause the material of interest to be released from the holding cavity and contraction of the activation material increases the size of the holding cavity to cause the material of interest to be received into the holding cavity. The at least one actuator is operable at multiple levels between a zero induction level to a maximum induction level on the activation material to thereby controllably expand or contract the holding cavity to release or receive a specified volume of the material of interest.

### BACKGROUND

There has been a growing interest in the use of microfluidic systems in chemical and biological sciences, medical specialties, as well as manufacturing and dispensing operations. This interest has been attributable to the potential increased performance of relatively complicated chemical and biochemical systems which use relatively small volumes of fluids. Microfluidic systems have been employed in these types of applications to introduce the fluids because such systems allow for more easily measured reactions. In addition, minimizing sample volumes have resulted in lowered reagent costs, less toxic material-introduction and more easily modeled reactions.

Microfluidic systems for drug delivery have until now used a contacting, but non-penetrating, patch, with or without enhancing agents, to move drugs diffusively through the skin. For those microfluidic systems that use a pump, the actuation unit is typically rather bulky in construction because the actuation units are oftentimes based upon conventional actuating devices, such as piezoelectric and thermoelectric actuators. Many fluids of interest, including drugs, however, are incapable of being delivered in precise extremely low dose amounts through use of these types of actuating devices, necessitating delivery of a larger volume of fluid for reliability and repeatability of the actuation unit. In addition, many drugs may become damaged or otherwise rendered unfit for their intended purposes through use of conventional actuating units.

### BRIEF DESCRIPTION OF THE DRAWINGS

Additional features of the present invention will become apparent to those skilled in the art from the following description with reference to the figures, in which:

FIG. 1A shows a block diagram of a microfluidic device for controlled release of material, according to an embodiment of the invention;

FIG. 1B shows a schematic diagram, partially in cross-section, of a part of a microfluidic device, according to an embodiment of the invention;

FIG. 1C shows a schematic diagram similar to FIG. 1B, where an activation system in the microfluidic device has expanded;

FIG. 1D shows a schematic diagram, partially in cross-section, of a part of a microfluidic device, according to another embodiment of the invention;

FIG. 1E shows a schematic diagram, partially in cross-section, of a part of a microfluidic device, according to a further embodiment of the invention;

FIG. 2 illustrates a graph depicting the amount of carbon dioxide gas evolved as a function of temperature;

FIGS. 3 and 4 depict flow diagrams of respective methods for delivering a material from a microfluidic device, according to two embodiments of the invention; and

FIG. 5 is a block diagram illustrating a computer system or other smart device operable to perform one or more functions on a microfluidic device, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures have not been described in detail so as not to unnecessarily obscure the embodiments.

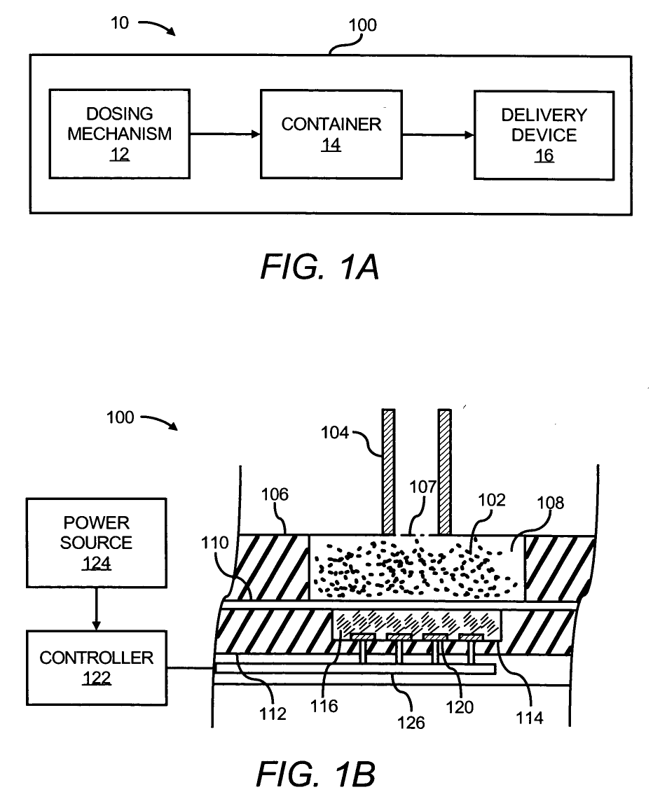

With reference first to FIG. 1A, a block diagram 10 of a microfluidic device 100 for controlled release of material is depicted, according to an example. It should be understood that the following description of the block diagram is but one manner of a variety of different manners in which such a microfluidic device 100 may be configured. In addition, it should be understood that the microfluidic device 100 may include additional components and that some of the components described herein may be removed and/or modified without departing from a scope of the microfluidic device 100. For instance, the microfluidic device 100 may include any number of sensors, memories, processors, air moving devices, vent tiles, etc., as well as other components, which may be implemented in the operations of the microfluidic device 100.

As shown in the block diagram 10 of FIG. 1A, the microfluidic device 100 includes a dosing mechanism 12, a container 14, and a delivery device 16. The dosing mechanism 12 may include a plunger or other actuation device capable of applying sufficient force on a material of interest contained in the container 14, such that the material of interest is released or received through the delivery device 16. In addition, the dosing mechanism 12 may operate to controllably release the material of interest from or receive the material of interest into the container 14, through the delivery device 16. It should further be noted that the dosing mechanism 12 may, in some instances, be a sampling mechanism configured to apply sufficient negative force to collect a material of interest through the delivery device 16.

The container 14 may include any reasonably suitable container for containing the material of interest and the delivery device 16 may include, for instance, a needle, an orifice, a tube, and the like.

A more detailed description of the elements forming the microfluidic device 100 is provided herein below with respect to FIGS. 1B-1E.

With reference first to FIG. 1B, there is shown a schematic diagram, partially in cross-section, of a part of the microfluidic device 100, according to an example. It should be readily apparent that the microfluidic device 100 depicted in FIG. 1B represents a generalized illustration and that other features may be added or existing features may be removed or modified without departing from a scope of the microfluidic device 100. For example, the microfluidic device 100 may include additional features as discussed herein below.

Generally speaking, the microfluidic device 100 may be employed to controllably deliver a material of interest 102, such as a drug, reagent or other type of material. More particularly, for instance, the microfluidic device 100 may be employed to inject or otherwise supply the material of interest 102 onto or through a surface, such as vial membrane or skin. In addition, or alternatively, the microfluidic device 100 may be employed to collect a sample of a specific volume of the material of interest 102. In any regard, the microfluidic device 100 may include a plurality of delivery orifices 104, which may include, for instance, microneedles, tubes, etc. In FIG. 1B, a single delivery orifice 104 is depicted for purposes of simplicity. It should be understood, however, that the microfluidic device 100 may include any reasonably suitable number of delivery orifices 104.

As shown in FIG. 1B, the delivery orifice 104 is attached to a first spacer layer 106. The first spacer layer 106 may include any reasonably suitable material, such as, silicon, glass, polymers, ceramics, etc. The first spacer layer 106 may be formed with a plurality of holding cavities 108 configured to house some or all of the material of interest 102. In addition, the holding cavities 108 may be associated with respective delivery orifices 104, such that the material of interest 102 contained in one of the holding cavities 108 may be delivered through one or more delivery orifices 104. It should be readily understood that a single holding cavity 108 is depicted in FIG. 1B for purposes of simplicity and not of limitation.

The microfluidic device 100 is also depicted as including an optional barrier 107 between the holding cavity 108 and the delivery orifice 104. The optional barrier 107 may generally operate to substantially prevent the material of interest 102 from being prematurely released through the delivery orifice. In addition, the optional barrier 107 may enable the material of interest 102 to flow into the delivery orifice 104 when sufficient pressure is applied on the material of interest 102 contained in the holding cavity 108. As such, the optional barrier 107 may include one or more openings configured to open or otherwise accommodate fluid movement when a sufficient amount of pressure is applied on the material of interest 102. In addition, or alternatively, the optional barrier 107 may be configured to rupture or otherwise create an opening when a sufficient amount of pressure is applied on the material of interest 102.

The barrier 107 is considered optional because the microfluidic device 100 may operate properly in certain instances without the use of the barrier 107. For instance, the delivery orifice 104 may include a hydrophobic needle capable of preventing delivery of the material of interest 102 until it is desired to do so, which therefore removes the barrier 107 requirement. It should, however, be understood that the barrier 107 may be used in conjunction with the hydrophobic needle without departing from a scope of the microfluidic device 100. In addition, the barrier 107 may be omitted, for instance, when the delivery orifice 104 includes a hydrophobic needle or when the material of interest 102 may otherwise remain within the holding cavity 108 without the use of the barrier 107, when the barrier 107 is not required to shield the material of interest 102, when the microfluidic device 100 is employed to collect samples of the material of interest 102, as shown in FIG. 1D, etc.

A bottom section of the holding cavity 108 is depicted as being formed by a membrane 110. As discussed in greater detail herein below, the membrane 110 includes a flexible membrane configured to change the size of the holding cavity 108. First, however, a discussion of a second spacer layer 112 is provided. The second spacer layer 112 may include the same material as the first spacer layer 106. Alternatively, however, the second spacer layer 112 may include a different material from the first spacer layer 106, and may include any of the materials listed above with respect to the first spacer layer 106.

According to an example, the first spacer layer 106 and the second spacer layer 112 may include a single component. In this example, the membrane 110 may be formed as part of the first spacer layer 106 and the second spacer layer 112, through, for instance, an etching process. In another example, the first spacer layer 106, the second spacer layer 112, and the membrane 110 may include separate elements that are bonded together.

In any regard, the second spacer layer 112 may include one or more actuation cavities 114 configured to house an activation material 116. The activation material 116 is operable to expand and cause the membrane 110 to deflect thereby causing the material of interest 102 to be released through the delivery orifice 104. Various examples of suitable activation materials 116 are described herein below. In addition, although a single actuation cavity 114 is depicted in FIG. 1A, it should be understood that the second spacer layer 112 may include any reasonably suitable number of actuation cavities 114 without departing from a scope of the microfluidic device 100 disclosed herein. The actuation cavity 114 may moreover include multiple compartments.

As also shown in FIG. 1B, a top section of the actuation cavity 114 may be formed by the membrane 110. The membrane 110 generally includes a flexible membrane configured to separate the activation material 116 from the material of interest 102 and to increase the size of the actuation cavity 114 as the activation material 116 expands, as shown in greater detail in FIG. 1C. More particularly, and as shown in FIG. 1C, expansion of the activation material 116 causes the membrane 110 above the actuation cavity 114 to deflect in a direction toward the delivery orifice 104. If the deflection of the membrane 110 also reduces the size of the holding cavity 108 for the material of interest 102, the material of interest 102 is then released from the delivery orifice 104, as shown as a released portion 118 of the material of interest 102.

According to another example, and as shown in FIG. 1D, the microfluidic device 100 may operate to draw a material of interest 102 into the holding cavity 108. In FIG. 1D, the activation material 116 is configured to decrease in size, thereby causing the membrane 110 to be deflected away from the delivery orifice 104 and the holding cavity 108 to increase in size. The increase in size of the holding cavity 108 generally causes a negative pressure to be created in the holding cavity 108, which causes the material of interest 102 to be drawn in through the delivery orifice 104, as indicated by the arrow 119.

The activation material 116 may, for instance, include EXPANCEL microspheres available from Expancel, Inc., having an office located in Duluth, Ga., USA. In this example, the activation material 116 may be in it's initial state and may expand when subjected to the appropriate amount of heat, thereby releasing the material of interest 102 through the delivery orifice 104; alternatively the activation material may be in a fully expanded state and may shrink when subjected to slightly higher heat, thereby drawing the material of interest 102 through the delivery orifice 104. The activation material 116 may also include hydrogels, which may be engineered to either expand or shrink in volume when heated above a threshold temperature or when subjected to a threshold pH level. Further examples of suitable activation materials 116 may include NH₃-water, CO₂-water, etc. The pH levels of these activation materials 116 may change through application of heat. For instance, application of heat on the activation material 116 including the CO₂-water will increase the pH of its solution as more and more CO₂ escapes from the solution. In addition, application of heat on the activation material 116 including the NH₃-water will decrease the pH of its solution as more and more NH₃ escapes out of the solution. CO₂ and NH₃ are two examples of materials that can change pH with application of temperature, it should be understood, however, that other materials having this property, which may be known to those skilled in the art, may also be employed. Additional examples of suitable activation materials 116 include, polyvinylchloride with one or more polyesters configured to shrink with applied heat, such as, shrink-wrap, shrink-tubing, etc.

In another example, an external vacuum system may be employed in addition to the activation material 116 to create the negative pressure in the holding cavity 108.

The microfluidic device 100 may be fabricated through any suitable fabrication process. For instance, the microfluidic device 100 may include a silicon or glass substrate and photolithography may be implemented to define the holding and actuation cavities 108 and 114. As another example, the microfluidic device 100 may include silicon, plastic, or other polymeric material and molding steps may be implemented to fabricate the microfluidic device 100. In addition, various combinations of etching, deposition, lithographic formation, molding, stamping, imprinting, etc., processes may be employed to fabricate the microfluidic device 100.

With reference back to FIG. 1B, also shown within the actuation cavity 114 are a plurality of actuators 120. As described in greater detail herein below, the actuators 120 may include various types of actuators and may be operated to controllably expand or contract the activation material 116. Although a plurality of actuators 120 have been illustrated in FIG. 1A, it should be understood that a single actuator 120 may be provided in the actuation cavity 114 without departing from a scope of the microfluidic device 100. In addition, the actuation cavity 114 may contain liquids, gels, solids, vapors, or a combination thereof, which may assist in the expansion or contraction of the activation material 116.

In any regard, the actuators 120 may be controlled on-board, for instance, through a conductive line 126, or remotely by a controller 122, which may include a microprocessor, a micro-controller, an application specific integrated circuit (ASIC), sensors, feedback devices and the like, configured to perform various processing functions. In addition, or alternatively, the controller 122 may include software operating in one or more computing devices. Furthermore, either or both of the controller 122 and a power source 124 may be integrally formed with the microfluidic device 100 or they may include devices that are separate from the microfluidic device 100.

In conjunction with the power source 124, the controller 122 may be configured to activate the actuators 120 according to one or more control schemes. For instance, the controller 122 may be configured to allow actuators 120 to be addressed in response to a local or remote command (for instance, through the push of an activation button or through receipt of a wireless signal). As another example, the controller 122 may be programmed to activate the actuators 120 at a predetermined time, or at predetermined intervals of time, etc. In addition, or alternatively, the controller 122 may be programmed to activate a single actuator, or one or more sets of actuators 120 to deliver the material of interest 102 from a first set of holding cavities 108 at a first time and to activate another set of actuators 120 to deliver the material of interest 102 from a second set of holding cavities 108 at a second time.

In addition, or alternatively, the controller 122 may be programmed to vary operations of the actuators 120 such that the actuators 120 may be operated at multiple levels between a zero induction level and a maximum induction level on the activation material 116 to thereby controllably expand or contract the holding cavity 108. As such, the controller 122 may control the amounts of the material of interest 102 that is released from or received in to the holding cavity 108 at various amounts between a zero amount and a maximum amount.

In one example, the controller 122 may vary the number of actuators 120 that are activated to thereby vary the induction levels applied on the activation material 116. In this example, the controller 122 may be programmed with data indicating the number of actuators 120 required to be activated in order to release a predetermined amount of the material of interest 102. For instance, the controller 122 may be programmed to activate two of the actuators 120 to release 30% of the material of interest 102, to activate three of the actuators 120 to release 50% of the material of interest 102, etc. Likewise, the controller 122 may be programmed to activate two of the actuators 120 to receive an amount of the material of interest 102 that fills 30% of the holding cavity 108, to activate three of the actuators 120 to receive an amount of the material of interest 102 that fills 60% of the holding cavity 108, etc.

In another example, the controller 122 may control the power supplied to the actuators 120. More particularly, for instance, the controller 122 may control the temperatures of the actuators 120 at multiple levels between a zero temperature change to a maximum temperature change, where a maximum temperature change is configured to expand or contract substantially all of the activation material 116. Additionally, the controller 122 may control the temperature changes of the actuators 120 for desired periods of time. For instance, the controller 122 may achieve a first temperature for a first period of time, a second temperature for a second period of time, a third temperature for a third period of time, etc. In this regard, the controller 122 may control the actuators 120 to deliver or receive the material of interest 102 in a multiple dose manner. In this example, the controller 122 may be programmed with data that indicates the amount of time the actuators 120 are required to receive energy to achieve the desired amount of movement of the material of interest 102, the amount of power the actuators 120 are required to receive to achieve the desired amount of movement, etc.

In any of the above examples, the microfluidic device 100 may include sufficiently small dimensions such that the microfluidic device 100 is capable of substantially accurately releasing or receiving pL, nL, and μL volumes. By way of example, the holding cavity 108 may include dimensions ranging between millimeter to micron scales, for instance, 1 mm×1 mm×1 mm, 500 μm×500 μm×500 μm, etc. In addition, the microfluidic device 100 may be manufactured through, for instance, imprinting, stamping, roll-to-roll processes as well as on discrete substrates and/or with more conventional lithographic processes, etc.

The controller 122 may be configured to instruct specific reservoirs to deliver one or more different types of materials at one or more different times. In one example, the controller 122 may be configured to control the delivery of a plurality of drugs based upon different delivery schedules and doses. In this example, the amount of material of interest 102 delivered may be controlled through control of the individual or sets of actuators 120 positioned in the various reservoirs as described above.

According to another example, the actuators 120 may be controllably activated to thereby create a desired level of expansion or contraction of the activation material 116 in a specific reservoir. In this example, the controller 122 may substantially accurately regulate the amount of the material of interest 102 released from or received by the specific reservoir by controlling the expansion or contraction of the activation material 116 in the specific reservoirs.

In one example, the actuators 120 may include resistive elements which experience a temperature rise in response to applied voltage. The resistive elements comprising the actuators 120 may differ from resistive elements employed in conventional thermal inkjet systems. For instance, in conventional thermal inkjet systems, the resistive elements are configured to heat up very rapidly and thereby cause a substance, such as ink, to vaporize and form a bubble. As the bubble expands, some of the substance/ink is expelled from a holding chamber. Once the bubble collapses, a vacuum is created which draws more of the substance/ink into the holding chamber from a reservoir. The holding chamber is re-filled with the substance and this process is repeated, but it is repeated under a single set of parameters. Any total fluid expelled is a quantized multiple of the number of times the system is fired. As such, simply holding the system at temperature longer does not expel more fluid.

The operating conditions useful for thermal inkjet typically induce damaging cavitation, creating spots of very high temperature and shock. In contrast, the resistive elements comprising the actuators 120 are configured to heat up relatively slower or in multiple stages. It should be noted that boiling is not the same as cavitation. The microfluidic device 100 disclosed herein is designed to operate without cavitational effects and to operate in an analog fashion (different predetermined amounts of the material of interest 102 may be expelled from or received through the delivery orifice 104 at one initiation). In this regard, the amounts of the material of interest 102 that are released or received may be controlled with relatively greater degrees of accuracy and control as compared with the use of thermal inkjet systems.

In this example, the activation material 116 may include a material configured to expand or contract when heated. For instance, the activation material 116 may include a liquid having a sufficiently low boiling point temperature such that the activation material 116 is vaporized through application of heat from the actuators 120. In addition, or alternatively, the activation material 116 may include a solid or a gel configured to expand through application of heat, such as the EXPANCEL microspheres discussed above. The activation material 116 may also include hydrogels engineered to expand or contract after reaching a threshold temperature or when subjected to a threshold pH level.

According to an example, the material of interest 102 contained in the holding cavity 108 may be processed to be highly water soluble to enable two-stage delivery of the material of interest 102. For instance, a reactant material may be kept in a separate holding cavity and maintained in solid form and just prior to release, or as part of the release, the reactant material may be mixed with a solvent/water to liquefy it or to place it in solution. By way of example, the reactant material may include a freeze-dried material in an extremely pure form, which may be made into a water-free powder that instantaneously goes into solution when brought in contact with the solvent/water. In this example, the freeze-dried material and the solvent/water may be housed in holding cavities 108 that are separated by a membrane configured to break when the activation material 116 is activated.

As another example, the freeze-dried material may be adhered or otherwise contained in the delivery orifice 104, such that, the freeze-dried material may be mixed with the solvent/water as the solvent/water is expelled from the holding cavity 108.

The activation material 116 may additionally, or alternatively, include a chemical configured to expand by evolving into a gas through receipt of a current. In this example, the actuators 120 may include devices configured to apply a current through the activation material 116 to thereby cause dissociation of the activation material 116 and expansion of the actuation cavity 114. By way of example, the activation material 116 may include a material configured to expand when heated. Examples of suitable activation materials 116 include ethyl alcohol, isopropyl alcohol, etc. In addition, the activation material 116 may include carbon dioxide in water or ammonia in water.

In another example, the microfluidic device 100 may be configured to deliver a mixture 130 of the activation material 116 and the material of interest 102. In this example, expansion of the activation material 116 may cause both the material of interest 102 and the activation material 116 to be released from the microfluidic device 100. In one regard, therefore, the activation material 116 may include a relatively inert material that does not substantially affect the material of interest 102 nor the target into which the mixture 130 is delivered.

An example of a microfluidic device 100′ configured to deliver the mixture 130 of the activation material 116 and the material of interest 102 is shown in FIG. 1E. Many of the elements depicted in FIG. 1E have the same reference numerals as those depicted in FIGS. 1B and 1C. It should be understood that those elements that share the same reference numerals are the same in all of the figures and thus a detailed discussion of those elements is omitted with respect to FIG. 1E. Instead, those elements in FIG. 1E that differ from the elements shown in FIGS. 1B and 1C are described with respect to FIG. 1E.

As shown, the microfluidic device 100′ includes a single chamber 132 that houses the mixture 130. The single chamber 132 may be formed in a layer 134 of silicon, glass, plastic, polymeric material, etc. In addition, as the activation material 116 expands, the mixture 130 is forced out of the delivery orifice 104. In one regard, therefore, the mixture 130 may contain a sufficient amount of activation material 116 to generally cause a sufficient amount of pressure inside the chamber 132 to cause a desired amount of the material of interest 102 to be released through the delivery orifice 104.

In one example, the activation material 116 may include a dissolved gas configured to remain in the dissolved state at a relatively lower temperature and is configured to return to the gaseous state around a relatively higher temperature. An example of a suitable activation material 116 includes carbon dioxide. More particularly, for instance, carbon dioxide may be dissolved in water within a pH range of around 4-9 and at a relatively lower temperature and the dissolved carbon dioxide may be distributed with a material of interest 102 to form the mixture 130. The gas capture is illustrated in the following examples:

CO₂+H₂O=>H₂CO₃

NH₃+H₂O=>NH₄⁺OH

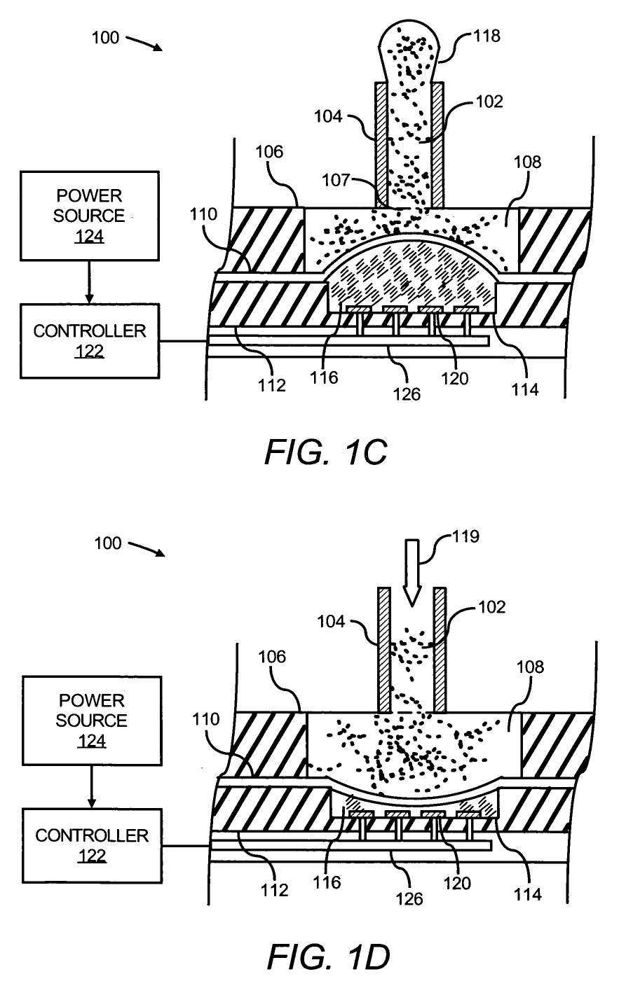

Moreover, the mixture 130 may be expanded through application of heat through the actuators 120 as described above. A graphical representation of how carbon dioxide may be employed as the activation material 116 is depicted in FIG. 2. More particularly, depicted in FIG. 2 is a graph 200 illustrating the amount of carbon dioxide gas evolved as a function of temperature, assuming a water volume of 1 pl Horizontal axis 202 of the graph 200 shows the temperature in degrees Celsius. Vertical axis 204 shows liters of gas evolved per μg of water (H₂O). Vertical axis 206 shows the solubility of carbon dioxide (CO₂) per 100 g of water (H₂O). In addition, the thinner line 208 indicates the grams of carbon dioxide dissolved per 100 grams of water at various temperatures and the thicker line 210 indicates the liters of gas evolved over a temperature of 20 degrees C.

As shown in FIG. 2, a relatively large amount of gas may be evolved from a relatively small amount of dissolved carbon dioxide. In this regard, carbon dioxide may be suitable for use as the activation material 116 in the microfluidic device 100′. In addition, the dissolved carbon dioxide may be employed as the activation material 116 in the microfluidic device 100 depicted in FIGS. 1B and 1C.

According to another example, the material of interest 102 may be combined in the activation material 116 and may be coated with a material (not shown) configured to protect the material of interest 102 from the activation material 116. In this example, the coating material may include a water insoluble, but enzyme removable material, such as polypeptides, gelatin, starch etc. Following injection/insertion of the material of interest 102, the coating may be stripped away by a reagent, bodily fluids, etc., which would make the material of interest 102 available for use in the system into which it was introduced.

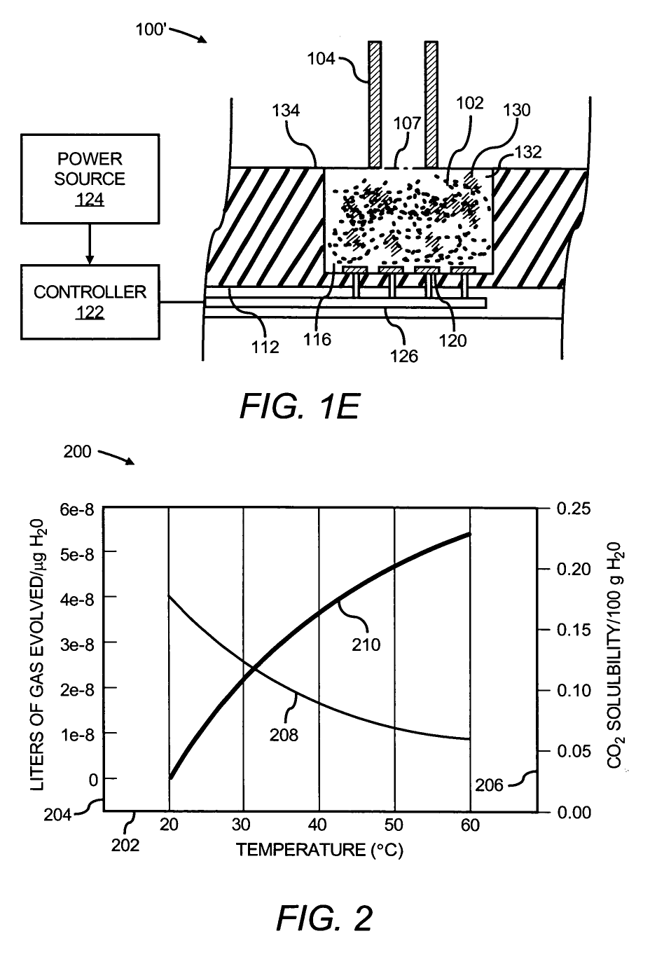

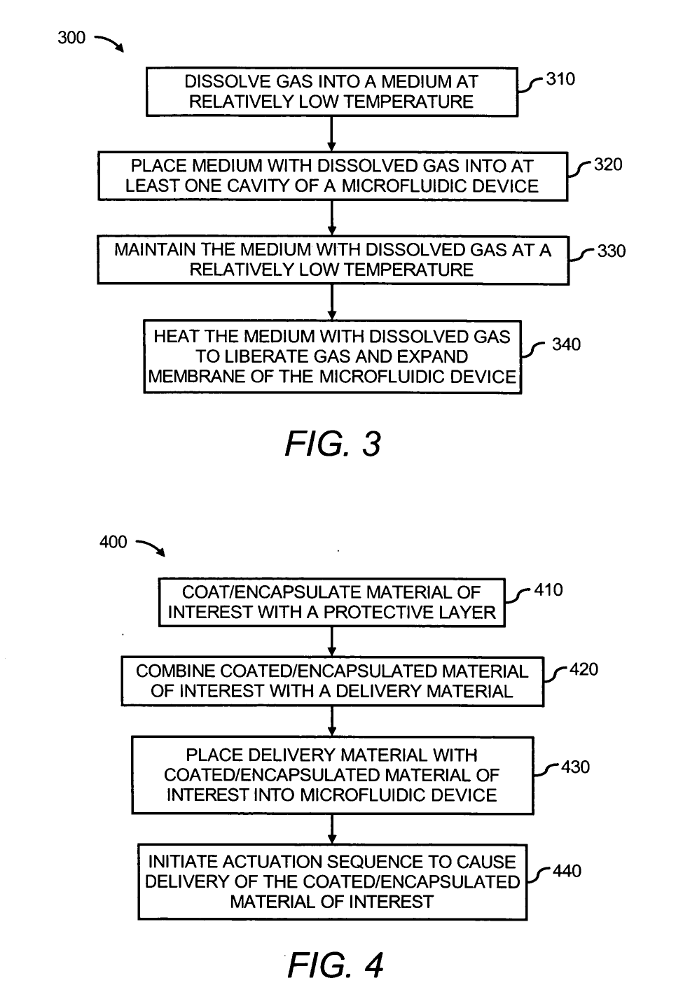

FIGS. 3 and 4 show flow diagrams of respective methods 300 and 400 for delivering a material of interest from a microfluidic device, according to two examples. It is to be understood that the following description of the methods 300 and 400 are but two manners of a variety of different manners in which examples of the invention may be practiced. It should also be apparent to those of ordinary skill in the art that the methods 300 and 400 represent generalized illustrations and that other steps may be added or existing steps may be removed, modified or rearranged without departing from the scopes of the methods 300 and 400.

The descriptions of the methods 300 and 400 are made with reference to the microfluidic devices 100, 100′ illustrated in FIGS. 1A-1E, and thus makes reference to the elements cited therein. It should, however, be understood that the methods 300 and 400 are not limited to the elements set forth in the microfluidic devices 100, 100′. Instead, it should be understood that the methods 300 and 400 may be practiced by a microfluidic device having a different configuration than that set forth in the microfluidic devices 100, 100′ depicted in FIGS. 1A-1E.

With particular reference first to FIG. 3, a gaseous activation material 116 is dissolved at a relatively low temperature at step 310. The gaseous activation material 116 may include carbon dioxide, ammonia, di-methyl ether, methyl ethyl ether or any water soluble or partial soluble gaseous chemicals, etc. For instance, carbon dioxide may be dissolved at a temperature according to the graph 200 depicted in FIG. 2.

At step 320, the dissolved gaseous activation material 116 may be inserted into at least one of the holding and actuation cavities 108, 114 of the microfluidic device 100, 100′. In a first example, the dissolved gaseous activation material 116 may be inserted into the actuation cavity 114 as illustrated in FIG. 1B to thereby maintain a separation between the dissolved gaseous activation material 116 and the holding cavity 108. In a second example, the dissolved gaseous activation material 116 may be combined with the material of interest 102 to form a mixture 130 and the mixture 130 may be housed in single chamber 132 of the microfluidic device 100′ depicted in FIG. 1E.

In either example, the dissolved gaseous activation material 116 housed in the microfluidic device 100, 100′ may be maintained at a relatively low temperature as indicated at step 330. Again, the relatively low temperature may be selected according to the correlations depicted in the graph 200, or any other temperature below the threshold of harm to the material of interest 102 or the maximum temperature of any part or subject in the delivery path.

In addition, at step 340, the dissolved gaseous activation material 116 may be heated to thereby evolve the gaseous activation material 116 back into a gaseous state and expand, where expansion of the gaseous activation material 116 causes the material of interest 102 to be released from the microfluidic device 100, 100′.

With reference now to FIG. 4, the material of interest 102 is coated with a protective layer comprising a substance that is water insoluble and removable by an enzyme at step 410. In addition, the coated material 102 may be immersed into an activation material 116 to form a mixture 130 at step 420. At step 430, the mixture 130 may be placed into a cavity 132 of the microfluidic device 100′, as shown in FIG. 1E.

At step 440, an actuation sequence may be initiated to cause delivery of the coated material of interest 102. In the actuation sequence, an actuator 120 may be activated to cause the activation material 116 to expand, where expansion of the activation material 116 forces the activation material 116 and the coated material of interest 102 to be delivered from the microfluidic device 100′.

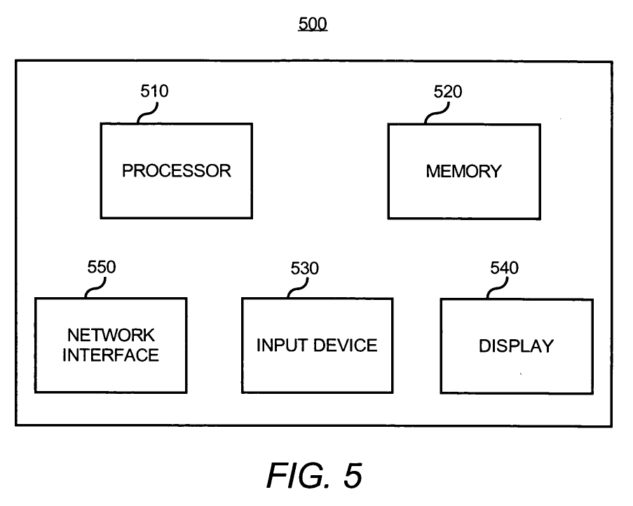

Referring to FIG. 5, a schematic diagram of a computer system 500 is shown in accordance with an embodiment. The computer system or other smart device 500 shown may be used as the controller 122 in the microfluidic devices 100, 100′ shown in FIG. 1A-1E. In one regard, computer system or other smart device 500 may be configured to receive various inputs and to control operations of the actuators 120 to thereby control delivery of the material 102 from the microfluidic devices 100, 100′. By way of example, system 500 may include software, internal or external storage media and a timing circuit to activate one or more of the actuators 120 after a predetermined time period or time intervals to cause a local increase in the temperature which causes the activation material 116 to expand and which then causes material of interest 102, such as a drug, to be delivered from the microfluidic device 100, 100′.

The system 500 may include a processor 510, which generally provides an execution platform for executing software for controlling the actuators 120. The system 500 also includes memory 520, which may include internal, external, fixed, removable, or programmable storage.

A user may interface with the system 500 with one or more input devices 530, such as a keyboard, a mouse, a stylus, and the like. The user may also interface with the system 500 with a display 540. A network interface 550, such as, telephone, IR, or other bus types, may be provided for communicating with other data storage, retrieval and analysis systems. One or more components of the system 500 may be considered optional, such as the display and input devices, and other types of components may be used or substituted without departing from a scope of the system 500.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

What is claimed is:

1. A microfluidic device for controllably moving a material of interest, said microfluidic device comprising:
a holding cavity configured to hold the material of interest;
at least one actuator configured to induce an activation material to one of expand and contract, wherein expansion of the activation material decreases the size of the holding cavity to thereby cause the material of interest to be released from the holding cavity and wherein contraction of the activation material increases the size of the holding cavity to thereby cause the material of interest to be received into the holding cavity,
wherein the at least one actuator is operable at multiple levels between a zero induction level to a maximum induction level on the activation material to thereby controllably one of expand and contract the holding cavity to release or receive a specified volume of the material of interest.

2. The microfluidic device according to claim 1, further comprising:
at least one delivery orifice configured for fluid communication with the holding cavity.

3. The microfluidic device according to claim 2, further comprising:
at least one of a barrier positioned between the at least one delivery orifice and the holding cavity, and wherein the at least one delivery orifice comprises a hydrophobic needle, wherein the material of interest is configured to flow through one or both of the at least one delivery orifice and the barrier when the activation material one of expands and contracts,

4. The microfluidic device according to claim 2, wherein the activation material comprises a gas configured to remain in a dissolved state at relatively lower temperatures and to evolve back into a gaseous state at relatively higher temperatures; and
wherein the at least one actuator is configured to increase the temperature of the activation material to evolve the activation material back into the gaseous state and thereby cause the material of interest to be released through the at least one delivery orifice.

5. The microfluidic device according to claim 2, wherein the activation material comprises a hydrogel configured to one of expand and contract with at least one of the application of heat and changes in pH; and
wherein the at least one actuator is configured to at least one of increase the temperature and change the pH of the activation material to one of expand and contract the hydrogel and thereby cause the material of interest to be moved through the at least one delivery orifice.

6. The microfluidic device according to claim 2, wherein the activation material comprises a liquid configured to remain in a liquid state at relatively lower temperatures and to transition into a gaseous state at relatively higher temperatures; and
wherein the at least one actuator is configured to increase the temperature of the activation material to vaporize the liquid into the gaseous state and thereby cause the material of interest to be released through the at least one delivery orifice.

7. The microfluidic device according to claim 2, wherein the activation material comprises a material configured to one of expand and contract the holding cavity and thereby cause the material of interest to be drawn into the holding cavity after a pre-vacuum treatment.

8. The microfluidic device according to claim 2, further comprising:
a space configured to hold at least one of a solvent and water;
a membrane separating the holding cavity and the space;
wherein the at least one actuator is configured to induce the activation material to expand thereby causing the membrane to break and enabling the material of interest and the at least one of the solvent and the water to mix prior to being moved out of the microfluidic device.

9. The microfluidic device according to claim 2, further comprising:
an actuation cavity housing the activation material, wherein the actuation cavity is separated from the holding cavity by a flexible membrane.

10. The microfluidic device according to claim 2, wherein the material of interest is interspersed with the activation material, and wherein expansion of the activation material causes the material of interest and the activation material to be released through the delivery orifice.

11. The microfluidic device according to claim 10, wherein the material of interest is substantially coated with a substance configured to substantially separate the material of interest from the activation material, wherein the substance is water insoluble and removable by an enzyme.

12. The microfluidic device according to claim 11, wherein the activation material comprises at least one of di-methyl ether and ethyl methyl ether.

13. The microfluidic device according to claim 2, wherein the activation material comprises a chemical configured to dissociate through application of a current from the at least one actuator; and
wherein the at least one actuator is configured to supply the current to the activation material, wherein the activation material is configured to expand through the dissociation caused by receipt of the current from the actuator, and wherein expansion of the activation material causes the material of interest to be released through the delivery orifice.

14. The microfluidic device according to claim 13, wherein the activation material comprises at least one of water, alcohol, and ammonia.

15. The microfluidic device according to claim 1, further comprising:
a power source for powering the at least one actuator;
a controller for controlling delivery of power to the at least one actuator, wherein the power source and the controller are integrally formed with the microfluidic device; and
wherein the at least one actuator comprises a resistive element configured to become heated through application of a potential difference, allowed by the controller.

16. The microfluidic device according to claim 1, wherein the material of interest is freeze dried in an extremely pure form.

17. The microfluidic device according to claim 1 wherein the activation material comprises carbon dioxide.

18. The microfluidic device according to claim 1, wherein the holding cavity comprises dimensions ranging between micron to millimeter scales.

19. A method for delivering a material of interest from a microfluidic device having at least one cavity and a delivery orifice, said method comprising:
dissolving a gaseous activation material at a relatively low temperature;
inserting the dissolved gaseous activation material into the at least one cavity of the microfluidic device;
maintaining the dissolved gaseous activation material at a relatively low temperature; and
heating the dissolved gaseous activation material to cause the dissolved gaseous activation material to evolve into a gaseous state and expand, wherein expansion of the gaseous activation material causes the material of interest to be delivered out of the delivery orifice.

20. The method according to claim 19, wherein the microfluidic device includes a holding cavity and an actuation cavity separated by a flexible membrane, and wherein inserting the dissolved gaseous activation material comprises inserting the dissolved gaseous activation material into the actuation cavity.

21. The method according to claim 19, further comprising:
combining the material of interest and the dissolved gaseous activation material into a mixture;
inserting the mixture into the at least one cavity; and
wherein heating the dissolved gaseous activation material further comprises heating the mixture of the material and the dissolved gaseous activation material.

22. A method for delivering a material of interest from a microfluidic device having a delivery orifice and an actuator, said method comprising:
coating the material of interest with a protective layer that is water insoluble and removable by an enzyme;
combining the coated material of interest into an activation material;
inserting the activation material with the coated material of interest into the microfluidic device; and
initiating an actuation sequence, wherein the actuation sequence causes the activation material to expand and forces the activation material and the coated material of interest to be delivered from the microfluidic device.
